(19) United States
(12) Patent Application Publication
(10) Pub. No.: US 2011/0253213 A1
(43) Pub. Date: Oct. 20, 2011

(54) THIN FILM SOLAR CELL

(76) Inventors: Jinhee PARK, Seoul (KR); Dongjoo You, Seoul (KR); Sunho Kim, Seoul (KR); Sehwon Ahn, Seoul (KR)

(21) Appl. No.: 13/175,639

(22) Filed: Jul. 1, 2011

(30) Foreign Application Priority Data
Nov. 23, 2010 (KR) 10-2010-0116662

(51) Int. Cl. H01L 31/0224

(52) U.S. Cl. 136/256

(57) ABSTRACT

A thin film solar cell is discussed. The thin film solar cell includes a substrate, a front electrode positioned on the substrate, a back electrode positioned on the front electrode, and a photoelectric conversion unit positioned between the front electrode and the back electrode. The front electrode includes first and second front electrode layers each containing a conductive material with light transmissivity. The first front electrode layer is formed on the substrate and contacts the substrate, and a porous pin hole exposing a portion of the substrate is formed in a portion of the first front electrode layer. The second front electrode layer contacts the first front electrode layer and covers the porous pin hole of the first front electrode layer.

This application claims priority to and the benefit of Korean Patent Application No. 10-2010-0116662 filed in the Korean Intellectual Property Office on Nov. 23, 2010, the entire contents of which are incorporated herein by reference.

### BACKGROUND OF THE INVENTION

1. Field of the Invention

Embodiments of the invention relate to a thin film solar cell.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts that have different conductive types, such as a p-type and an n-type, and form a p-n junction, and electrodes respectively connected to the semiconductor parts of the different conductive types.

When light is incident on the solar cell, a plurality of electron-hole pairs are generated in the semiconductor parts. The electron-hole pairs are separated into electrons and holes by the photovoltaic effect. Thus, the separated electrons move to the n-type semiconductor part and the separated holes move to the p-type semiconductor part, and then the electrons and holes are collected by the electrodes electrically connected to the n-type semiconductor part and the p-type semiconductor part, respectively. The electrodes are connected to each other using electric wires to thereby obtain electric power.

### SUMMARY OF THE INVENTION

In one aspect, there is a thin film solar cell including a substrate, a front electrode positioned on the substrate, the front electrode including a first front electrode layer and a second front electrode layer each containing a conductive material with light transmissivity, a back electrode positioned on the front electrode, and a photoelectric conversion unit positioned between the front electrode and the back electrode, the photoelectric conversion unit configured to receive light and convert the light into electricity, wherein the first front electrode layer is formed on the substrate and contacts the substrate, and a hole exposing a portion of the substrate is formed in a portion of the first front electrode layer, and the second front electrode layer contacts the first front electrode layer and covers the porous pin hole of the first front electrode layer.

The second front electrode layer may contain a material obtained by mixing at least one of zinc oxide (ZnO), tin dioxide (SnO₂), and titanium dioxide (TiO₂) with a metal material.

The first front electrode layer may contain aluminum-doped zinc oxide (AZO), and the second front electrode layer may contain boron-doped zinc oxide (BZO).

An average thickness of the second front electrode layer may be less than an average thickness of the first front electrode layer. The average thickness of the second front electrode layer may be approximately 50 nm to 500 nm. The second front electrode layer may have a uniform thickness within the margin of error. The average thickness of the first front electrode layer may be approximately 300 nm to 900 nm.

A surface of the first front electrode layer and a surface of the second front electrode layer may be textured. An inclined angle of a textured surface of the second front electrode layer may be less than an inclined angle of a textured surface of the first front electrode layer.

The photoelectric conversion unit may have at least one p-i-n structure including a p-type semiconductor layer, an intrinsic semiconductor layer, and an n-type semiconductor layer. The intrinsic semiconductor layer of the photoelectric conversion unit may contain germanium (Ge). The intrinsic semiconductor layer of the photoelectric conversion unit may contain at least one of amorphous silicon and microcrystalline silicon.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 illustrates a thin film solar cell according to an example embodiment of the invention;

FIG. 2 illustrates an example of a porous pin hole formed in a portion of a first front electrode layer;

FIG. 3 illustrates a first front electrode layer and a second front electrode layer according to an example embodiment of the invention;

FIG. 4 illustrates an example of an application of a thin film solar cell including first and second front electrode layers according to an example embodiment of the invention to a double junction solar cell having a p-i-n/p-i-n structure; and

FIG. 5 illustrates an example of an application of a thin film solar cell including first and second front electrode layers according to an example embodiment of the invention to a triple junction solar cell having a p-i-n/p-i-n/p-i-n structure.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

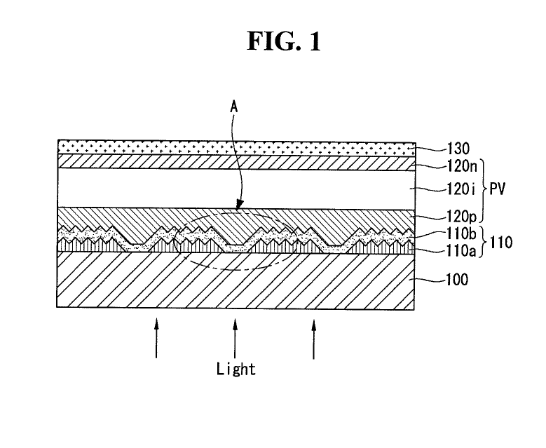

FIG. 1 illustrates a thin film solar cell according to an example embodiment of the invention. More specifically, FIG. 1 illustrates a thin film solar cell including a photoelectric conversion unit having a p-i-n structure based on an incident surface of a substrate. Additionally, the photoelectric conversion unit may have an n-i-p structure based on the incident surface of the substrate. In the following description, the photoelectric conversion unit having the p-i-n structure based on the incident surface of the substrate is taken as an example for the sake of brevity.

As shown in FIG. 1, a thin film solar cell according to an example embodiment of the invention includes a substrate 100, a front electrode 110, a photoelectric conversion unit PV, and a back electrode 130. The front electrode 110 includes a first front electrode layer 110a and a second front electrode layer 110b, each of which contains a conductive material with light permeability or transmissivity.

The front electrode 110 is positioned on the substrate 100, and the back electrode 130 is positioned on the front electrode 110. The photoelectric conversion unit PV is positioned between the front electrode 110 and the back electrode 130 and converts light incident on an incident surface of the substrate 100 into electricity.

The substrate 100 may provide a space for other functional layers. The substrate 100 may be formed of a substantially transparent non-conductive material, for example, glass or plastic, so that light incident on the substrate 100 efficiently reaches the photoelectric conversion unit PV.

The front electrode 110 positioned on the substrate 100 includes the first front electrode layer 110a and the second front electrode layer 110b, each of which contains a substantially conductive material with light permeability or transmissivity, so as to increase a transmittance of incident light. A specific resistance of the front electrode 110 may be about 10⁻² Ω·cm to 10⁻¹ Ω·cm. The detailed description of the first front electrode layer 110a and the second front electrode layer 110b follows the basic description of the front electrode 110, the photoelectric conversion unit PV, and the back electrode 130.

The front electrode 110 may be electrically connected to the photoelectric conversion unit PV. Hence, the front electrode 110 may collect carriers (for example, holes) produced by the incident light and may output the carriers.

A plurality of uneven portions may be formed on an upper surface of the front electrode 110, and the uneven portions may have a non-uniform pyramid structure. In other words, the front electrode 110 may have a textured surface. As discussed above, when the surface of the front electrode 110 is textured, the front electrode 110 may reduce a reflectance of incident light and increase an absorptance of the incident light. Hence, the efficiency of the thin film solar cell may be improved. Although FIG. 1 shows only the uneven portions of the front electrode 110, the photoelectric conversion unit PV may have a plurality of uneven portions.

The back electrode 130 may be formed of metal with high electrical conductivity so as to increase a recovery efficiency of electric power produced by the photoelectric conversion unit PV. The back electrode 130 electrically connected to the photoelectric conversion unit PV may collect carriers (for example, electrons) produced by incident light and may output the carriers.

The photoelectric conversion unit PV is positioned between the front electrode 110 and the back electrode 130 and produces the electric power using light coming from the outside.

The photoelectric conversion unit PV may have the p-i-n structure including a p-type semiconductor layer 120p, an intrinsic (called i-type) semiconductor layer 120i, and an n-type semiconductor layer 120n that are sequentially formed on the incident surface of the substrate 100 in the order named. Other layers may be included or present in the photoelectric conversion unit PV.

The p-type semiconductor layer 120p may be formed using a gas obtained by adding impurities of a group III element, such as boron (B), gallium (Ga), and indium (In), to a raw gas containing silicon (Si).

The i-type semiconductor layer 120i may prevent or reduce a recombination of carriers and may absorb light. The i-type semiconductor layer 120i may absorb incident light to produce carriers such as electrons and holes. The i-type semiconductor layer 120i may be a semiconductor of various kind, and may be one containing microcrystalline silicon (mc-Si), for example, hydrogenated microcrystalline silicon (mc-Si:H). Alternatively, the i-type semiconductor layer 120i may contain amorphous silicon (a-Si), for example, hydrogenated amorphous silicon (a-Si:H).

The n-type semiconductor layer 120n may be formed using a gas obtained by adding impurities of a group V element, such as phosphorus (P), arsenic (As), and antimony (Sb), to a raw gas containing silicon (Si).

The photoelectric conversion unit PV may be formed using a chemical vapor deposition (CVD) method, such as a plasma enhanced CVD (PECVD) method.

In the photoelectric conversion unit PV shown in FIG. 1, the p-type semiconductor layer 120p and the n-type semiconductor layer 120n may form a p-n junction with the i-type semiconductor layer 120i interposed therebetween.

In such a structure of the thin film solar cell shown in FIG. 1, when light is incident on the p-type semiconductor layer 120p, a depletion region is formed inside the i-type semiconductor layer 120i because of the p-type semiconductor layer 120p and the n-type semiconductor layer 120n each having a relatively high doping concentration, thereby generating an electric field. Electrons and holes produced in the i-type semiconductor layer 120i corresponding to a light absorbing layer are separated from each other by a contact potential difference through a photovoltaic effect and move in different directions. For example, the holes may move to the front electrode 110 through the p-type semiconductor layer 120p, and the electrons may move to the back electrode 130 through the n-type semiconductor layer 120n. Hence, the electric power may be produced.

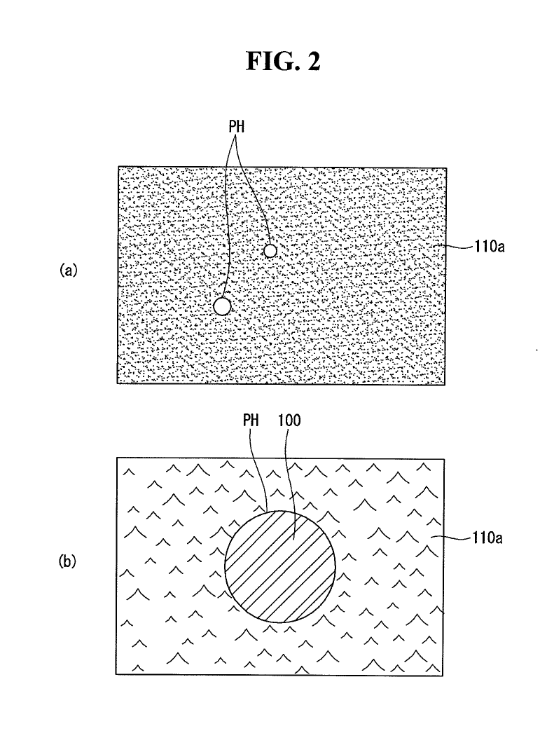

The first front electrode layer 110a of the front electrode 110 is formed on the substrate 100 and contacts the substrate 100. As shown in (a) and (b) of FIG. 2, a plurality of holes, such as porous pin holes PH exposing a portion of the substrate 100 are formed in a portion of the first front electrode layer 110a. Accordingly, as shown in FIG. 1, the second front electrode layer 110b of the front electrode 110 contacts the first front electrode layer 110a and is formed to cover (and/or fill-in for) the first front electrode layer 110a. Hence, the second front electrode layer 110b is formed to cover the porous pin holes PH of the first front electrode layer 110a. In other words, the first front electrode layer 110a and the second front electrode layer 110b contact the substrate 100 and may be sequentially formed on the substrate 100.

As discussed above, when the front electrode 110 has the double-layered structure, the photoelectric efficiency of the thin film solar cell is improved.

Although FIG. 2 shows the circular porous pin holes PH of the first front electrode layer 110a, the porous pin holes PH may have other shapes, such as an oval shape, a lattice shape, various polygon shapes, or irregular shapes. In other words, the shape of the porous pin hole PH is not particularly limited as long as the porous pin hole PH exposes a portion of the substrate 100 on which the first front electrode layer 110a is formed.

Further, (b) of FIG. 2 illustrates particles of the first front electrode layer 110a not remaining inside the porous pin hole PH in various embodiments of the invention. However, the particles of the first front electrode layer 110a may remain inside the porous pin hole PH. In embodiments of the invention, the form of the porous pin holes may be a grouping of numerous small holes as opposed to simply a few larger holes.

In embodiments of the invention, the porous pin holes may be distributed over the first front electrode layer 110a in various manners, and may be randomly distributed or evenly distributed. Also, a density of the porous pin holes over the first front electrode layer 110a may range from about 1 to 5 per square μm. In embodiments of the invention, an average diameter of each of the porous pin holes may be 200 nm to 1000 nm. Accordingly, the average diameter of each of the porous pin holes may be one of less than, equal to, or greater than the thickness of the first front electrode layer 110a.

The porous pin hole PH of the first front electrode layer 110a is formed during a process, in which the surface of the first front electrode layer 110a is etched to form a textured surface in order to improve the trapping of the incident light inside the photoelectric conversion unit PV. The porous pin hole PH may be formed where etching of the first front electrode layer 110a proceeded faster than other portions of the first front electrode layer 110a and/or where the first front electrode layer 110a was thinner to start with, for example.

Unlike the embodiment of the invention, if the photoelectric conversion unit PV containing silicon is formed directly on the first front electrode layer 110a, the porous pin holes PH of the first front electrode layer 110a may serve as a defect capable of weakening an operation (or decreasing the efficiency) of the photoelectric conversion unit PV.

More specifically, if the second front electrode layer 110b is not formed on the first front electrode layer 110a, and the photoelectric conversion unit PV containing silicon is formed directly on the first front electrode layer 110a, the photoelectric conversion unit PV may directly contact the substrate 100 in the porous pin holes PH of the first front electrode layer 110a. In this instance, the defect of the photoelectric conversion unit PV may be generated because of an unstable combination of carriers in a portion of the photoelectric conversion unit PV directly contacting the substrate 100. Furthermore, cracks may be generated in the portion of the photoelectric conversion unit PV directly contacting the substrate 100, thereby reducing the photoelectric efficiency of the thin film solar cell.

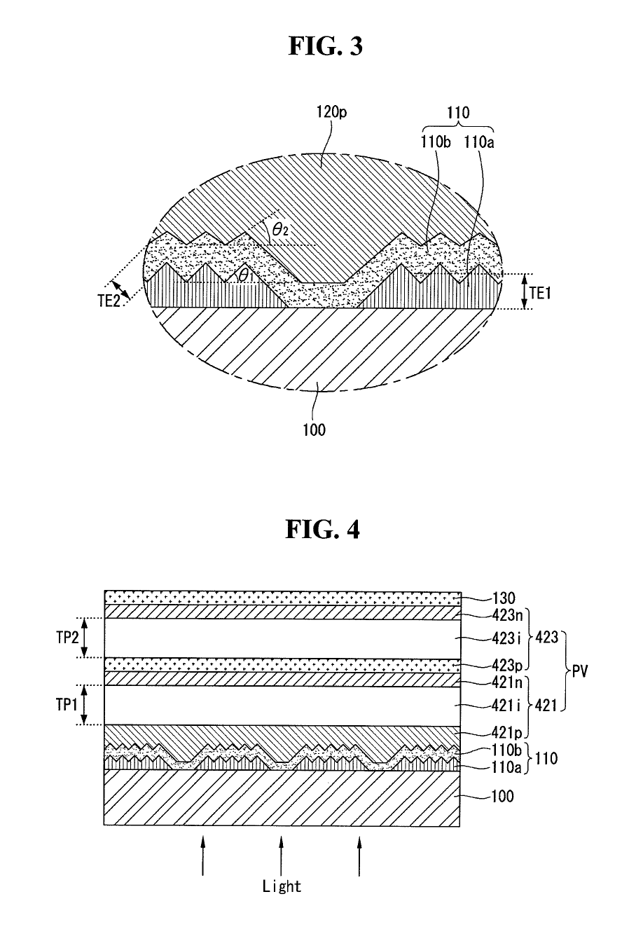

On the other hand, as shown in FIG. 3, in the embodiment of the invention, because the second front electrode layer 110b contacts and covers the first front electrode layer 110a, the photoelectric conversion unit PV is prevented from directly contacting the substrate 100 in the porous pin holes PH of the first front electrode layer 110a. Hence, the unstable combination of carriers in the photoelectric conversion unit PV is reduced or prevented. Furthermore, the generation of cracks in the photoelectric conversion unit PV is prevented. As a result, the photoelectric efficiency of the thin film solar cell is improved.

The first front electrode layer 110a may be formed of a material having high light transmittance and high electrical conductivity, so as to transmit most of incident light and pass through an electric current. More specifically, the first front electrode layer 110a may be formed of at least one selected from the group consisting of indium tin oxide (ITO), tin-based oxide (for example, SnO₂), AgO, ZnO—Ga₂O₃ (or ZnO—Al₂O₃), fluorine tin oxide (FTO), and a combination thereof. For example, the first front electrode layer 110a may be formed of aluminum-doped zinc oxide (ZnO:Al or AZO).

When the first front electrode layer 110a is formed of AZO, it is relatively easier to control the shape of the textured surface of the first front electrode layer 110a when a chemical etching process is performed to texture the surface of the first front electrode layer 110a, as compared to the first front electrode layer 110a formed of fluorine-doped tin dioxide (SnO₂:F). Further, the light transmittance and the electrical conductivity of the first front electrode layer 110a formed of AZO are relatively high. Further, it is easier to control haze, which is an important variable in the improvement of light characteristics by increasing light scattering. As a result, the photoelectric efficiency of the thin film solar cell is improved because of an increase in a light path resulting from the increase in the light scattering.

The second front electrode layer 110b may contain a material obtained by mixing at least one of zinc oxide (ZnO), tin dioxide (SnO₂), and titanium dioxide (TiO₂) with a metal material. For example, the second front electrode layer 110b may contain boron-doped zinc oxide (ZnO:B, BZO).

The second front electrode layer 110b may be formed using a low pressure chemical vapor deposition (LPCVD) method.

For example, the second front electrode layer 110b containing BZO may be formed by mixing diethyl zinc (DEZ) and diborane (B₂H₆) with water vapor gas and depositing the mixture at a temperature of about 100° C. to 250° C. using the LPCVD method.

The LPCVD method used to form the second front electrode layer 110b is more advantageous than a deposition method using a sputter in step coverage. Hence, the mixture may be deposited on the textured surface (i.e., the non-uniform surface) of the first front electrode layer 110a to the relatively uniform thickness.

As shown in FIG. 3, an average thickness TE2 of the second front electrode layer 110b may be less than an average thickness TE1 of the first front electrode layer 110a. The reason for this is to sufficiently secure the thickness of the first front electrode layer 110a when the surface of the first front electrode layer 110a is textured so as to increase the light scattering.

As discussed above, because the average thickness TE2 of the second front electrode layer 110b is less than the average thickness TE1 of the first front electrode layer 110a, the shape of the textured surface of the first front electrode layer 110a is considerably similar to the shape of the surface of the second front electrode layer 110b even if the second front electrode layer 110b is formed. For this, the second front electrode layer 110b may have the uniform thickness within a margin of error. In embodiments of the invention, such a margin may be about 5 nm to 50 nm

In the embodiment of the invention, the average thickness TE1 of the first front electrode layer 110a may be about 300 nm to 900 nm. The reason why the average thickness TE1 of the first front electrode layer 110a is equal to or greater than about 300 nm is to minimize the number of porous pin holes PH generated when the etching process is performed on the surface of the first front electrode layer 110a to form the textured surface. Further, the reason why the average thickness TE1 of the first front electrode layer 110a is equal to or less than about 900 nm is that the first front electrode layer 110a has at least a minimum light transmittance that may be acceptable. In other words, when the average thickness TE1 of the first front electrode layer 110a is excessively large, an amount of light absorbed in the photoelectric conversion unit PV may be reduced. Therefore, the average thickness TE1 of the first front electrode layer 110a is equal to or less than about 900 nm so that the first front electrode layer 110a has at least the minimum light transmittance, thereby preventing a reduction in the amount of light absorbed in the photoelectric conversion unit PV.

In the embodiment of the invention, the average thickness TE2 of the second front electrode layer 110b may be about 50 nm to 500 nm. The reason why the average thickness TE2 of the second front electrode layer 110b is equal to or greater than about 50 nm is that when the average thickness TE2 of the second front electrode layer 110b is excessively small, it is insufficient to fill the porous pin holes PH of the first front electrode layer 110a with the second front electrode layer 110b. Further, the reason why the average thickness TE2 of the second front electrode layer 110b is equal to or less than about 500 nm is that the second front electrode layer 110b should have at least the minimum light transmittance.

An inclined angle θ2 of a textured surface of the second front electrode layer 110b may be less than an inclined angle θ1 of the textured surface of the first front electrode layer 110a. The difference between the inclined angles θ1 and θ2 is caused by characteristics of materials related to the first front electrode layer 110a being formed of AZO and the second front electrode layer 110b being formed of BZO.

As discussed above, when the inclined angle θ2 of the textured surface of the second front electrode layer 110b is less than the inclined angle θ1 of the textured surface of the first front electrode layer 110a, the scattering characteristic of light that is transmitted through the first and second front electrode layers 110a and 110b may be further improved.

In the embodiment of the invention shown in FIG. 3, an upper surface of a portion of the second electrode layer 110b positioned in the porous pin hole is shown as receded into the porous pin hole so as to form a depression at the porous pin hole. However, in other embodiments of the invention, the upper surface of the portion of the second electrode layer 110b positioned in the porous pin hole may be formed without the depression. In such an instance, a thickness of the second electrode layer 110b positioned in the porous pin hole may be greater than TE2. Additionally, the upper surface of the portion of the second electrode layer 110b positioned in the porous pin hole may be planarized or may be formed with a plurality of the uneven portions. Also, walls of the porous pin holes through the first front electrode layer 110a need not be inclined, and they may be vertical, or may even be inclined in an opposite direction from that shown in FIG. 3. That is, the porous pin holes may be wider at the bottom than at the top.

FIGS. 1 to 3 illustrate the thin film solar cell having the p-i-n structure. Additionally, the thin film solar cell including the first and second front electrode layers 110a and 110b according to the embodiment of the invention may be applied to a tandem solar cell, for example, a double junction solar cell or a triple junction solar cell. Further, the thin film solar cell including the first and second front electrode layers 110a and 110b according to the embodiment of the invention may be applied to other types of solar cells in other embodiments.

FIG. 4 illustrates an example of an application of the thin film solar cell including the first and second front electrode layers according to the example embodiment of the invention to a double junction solar cell having a p-i-n/p-i-n structure. In the following explanations, structural elements having the same functions and structures as those discussed previously are designated by the same reference numerals, and the explanations therefore will not be repeated unless they are necessary.

As shown in FIG. 4, a thin film solar cell may include a first photoelectric conversion unit 421 and a second photoelectric conversion unit 423. More specifically, a first p-type semiconductor layer 421p, a first i-type semiconductor layer 421i, a first n-type semiconductor layer 421n, a second p-type semiconductor layer 423p, a second i-type semiconductor layer 423i, and a second n-type semiconductor layer 423n may be sequentially stacked on an incident surface of a substrate 100 in the order named. Other layers may be included or present in the first and/or second photoelectric conversion units or therebetween.

The first i-type semiconductor layer 421i may mainly absorb light of a short wavelength band to produce electrons and holes. The second i-type semiconductor layer 423i may mainly absorb light of a long wavelength band to produce electrons and holes.

As discussed above, because the double junction solar cell absorbs light of the short wavelength band and light of the long wavelength band to produce carriers, the efficiency of the double junction solar cell may be improved.

A thickness TP2 of the second i-type semiconductor layer 423i may be greater than a thickness TP1 of the first i-type semiconductor layer 421i, so as to sufficiently absorb light of the long wavelength band.

The first i-type semiconductor layer 421i of the first photoelectric conversion unit 421 and the second i-type semiconductor layer 423i of the second photoelectric conversion unit 423 may contain amorphous silicon. Alternatively, the first i-type semiconductor layer 421i of the first photoelectric conversion unit 421 may contain amorphous silicon, and the second i-type semiconductor layer 423i of the second photoelectric conversion unit 423 may contain microcrystal line silicon.

In the double junction thin film solar cell shown in FIG. 4, the second i-type semiconductor layer 423i of the second photoelectric conversion unit 423 may be doped with germanium (Ge) as impurities. Because germanium (Ge) may reduce a band gap of the second i-type semiconductor layer 423i, an absorptance of the second i-type semiconductor layer 423i with respect to light of the long wavelength band may increase. Hence, the efficiency of the double junction thin film solar cell may be improved.

In other words, in the double junction thin film solar cell, the first i-type semiconductor layer 421i may absorb light of the short wavelength band to provide the photoelectric effect, and the second i-type semiconductor layer 423i may absorb light of the long wavelength band to provide the photoelectric effect. Further, because the band gap of the second i-type semiconductor layer 423i doped with Ge may be reduced, the second i-type semiconductor layer 423i may absorb a large amount of light of the long wavelength band. As a result, the efficiency of the double junction thin film solar cell may be improved.

The PECVD method may be used to dope the second i-type semiconductor layer 423i with Ge. In the PECVD method, a very high frequency (VHF), a high frequency (HF), or a radio frequency (RF) may be applied to a chamber filled with Ge gas.

In the embodiment of the invention, an amount of Ge contained in the second i-type semiconductor layer 423i may be about 3 to 20 atom %. When the amount of Ge is within the above range, the band gap of the second i-type semiconductor layer 423i may be sufficiently reduced. Hence, an absorptance of the second i-type semiconductor layer 423i with respect to light of the long wavelength band may increase.

Even in this instance, the first i-type semiconductor layer 421i may mainly absorb light of the short wavelength band to produce electrons and holes. The second i-type semiconductor layer 423i may mainly absorb light of the long wavelength band to produce electrons and holes.

In the double junction thin film solar cell shown in FIG. 4, a front electrode 110 includes a first front electrode layer 110a and a second front electrode layer 110b. The first front electrode layer 110a is formed on the substrate 100 and contacts the substrate 100, and a plurality of porous pin holes exposing a portion of the substrate 100 are formed in a portion of the first front electrode layer 110a. The second front electrode layer 110b contacts the first front electrode layer 110a and is formed to cover the first front electrode layer 110a.

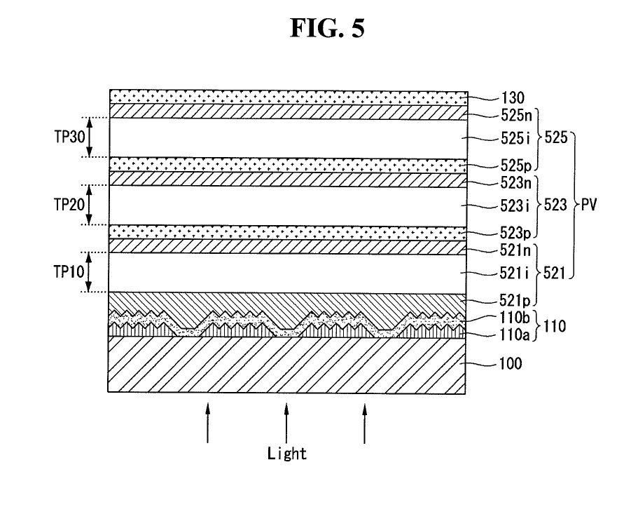

FIG. 5 illustrates an example of an application of the thin film solar cell including the first and second front electrode layers according to the example embodiment of the invention to a triple junction solar cell having a p-i-n/p-i-n/p-i-n structure. In the following explanations, structural elements having the same functions and structures as those discussed previously are designated by the same reference numerals, and the explanations therefore will not be repeated unless they are necessary.

As shown in FIG. 5, the triple junction thin film solar cell according to the embodiment of the invention may include a first photoelectric conversion unit 521, a second photoelectric conversion unit 523, and a third photoelectric conversion unit 525 that are sequentially positioned on a light incident surface of a substrate 100 in the order named.

Each of the first photoelectric conversion unit 521, the second photoelectric conversion unit 523, and the third photoelectric conversion unit 525 may have the p-i-n structure. A first p-type semiconductor layer 521p, a first i-type semiconductor layer 521i, a first n-type semiconductor layer 521n, a second p-type semiconductor layer 523p, a second i-type semiconductor layer 523i, a second n-type semiconductor layer 523n, a third p-type semiconductor layer 525p, a third i-type semiconductor layer 525i, and a third n-type semiconductor layer 525n may be sequentially positioned on the substrate 100 in the order named. Other layers may be included or present in the first, second and/or third photoelectric conversion units or therebetween.

The first i-type semiconductor layer 521i, the second i-type semiconductor layer 523i, and the third i-type semiconductor layer 525i may be variously implemented.

As a first example, the first i-type semiconductor layer 521i and the second i-type semiconductor layer 523i may contain amorphous silicon (a-Si), and the third i-type semiconductor layer 525i may contain microcrystalline silicon (mc-Si). A band gap of the second i-type semiconductor layer 523i may be reduced by doping the second i-type semiconductor layer 523i with Ge. Alternatively, both the second i-type semiconductor layer 523i and the third i-type semiconductor layer 525i may be doped with Ge.

Alternatively, as a second example, the first i-type semiconductor layer 521i may contain amorphous silicon (a-Si), and the second i-type semiconductor layer 523i and the third i-type semiconductor layer 525i may contain microcrystalline silicon (mc-Si). A band gap of the third i-type semiconductor layer 525i may be reduced by doping the third i-type semiconductor layer 525i with Ge.

The first photoelectric conversion unit 521 may absorb light of a short wavelength band, thereby producing electric power. The second photoelectric conversion unit 523 may absorb light of a middle wavelength band between the short wavelength band and a long wavelength band, thereby producing electric power. The third photoelectric conversion unit 525 may absorb light of the long wavelength band, thereby producing electric power.

A thickness TP30 of the third i-type semiconductor layer 525i may be greater than a thickness TP20 of the second i-type semiconductor layer 523i, and the thickness TP20 of the second i-type semiconductor layer 523i may be greater than a thickness TP10 of the first i-type semiconductor layer 521i. Hence, an absorptance of the third i-type semiconductor layer 525i with respect to light of the long wavelength band may further increase.

Because the triple junction thin film solar cell shown in FIG. 5 may absorb light of a wider band, the production efficiency of the electric power of the triple junction thin film solar cell may be improved.

In the triple junction thin film solar cell shown in FIG. 5, a front electrode 110 includes a first front electrode layer 110a and a second front electrode layer 110b. The first front electrode layer 110a is formed on the substrate 100 and contacts the substrate 100, and a plurality of porous pin holes exposing a portion of the substrate 100 are formed in a portion of the first front electrode layer 110a. The second front electrode layer 110b contacts the first front electrode layer 110a and is formed to cover the first front electrode layer 110a.

In various embodiments of the invention, the one or more photoelectric conversion units of the thin film solar cell may be formed of any semiconductor material. Accordingly, materials for the one or more photoelectric conversion units may include Cadmium telluride (CdTe), Copper indium gallium selenide (CIGS) and/or other materials, including other thin film solar cell materials.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A thin film solar cell comprising:
a substrate;
a front electrode positioned on the substrate, the front electrode including a first front electrode layer and a second front electrode layer each containing a conductive material with light transmissivity;
a back electrode positioned on the front electrode; and
a photoelectric conversion unit positioned between the front electrode and the back electrode, the photoelectric conversion unit configured to receive light and convert the light into electricity,
wherein the first front electrode layer is formed on the substrate and contacts the substrate, and a hole exposing a portion of the substrate is formed in a portion of the first front electrode layer, and
the second front electrode layer contacts the first front electrode layer and covers the hole of the first front electrode layer.

2. The thin film solar cell of claim 1, wherein the second front electrode layer contains a material obtained by mixing at least one of zinc oxide (ZnO), tin dioxide (SnO₂), and titanium dioxide (TiO₂) with a metal material.

3. The thin film solar cell of claim 1, wherein the first front electrode layer contains aluminum-doped zinc oxide (AZO), and the second front electrode layer contains boron-doped zinc oxide (BZO).

4. The thin film solar cell of claim 1, wherein an average thickness of the second front electrode layer is less than an average thickness of the first front electrode layer.

5. The thin film solar cell of claim 4, wherein the average thickness of the second front electrode layer is approximately 50 nm to 500 nm.

6. The thin film solar cell of claim 5, wherein the second front electrode layer has a uniform thickness within a margin of error.

7. The thin film solar cell of claim 4, wherein the average thickness of the first front electrode layer is approximately 300 nm to 900 nm.

8. The thin film solar cell of claim 1, wherein a surface of the first front electrode layer and a surface of the second front electrode layer are textured, and
an inclined angle of a textured surface of the second front electrode layer is less than an inclined angle of a textured surface of the first front electrode layer.

9. The thin film solar cell of claim 1, wherein the photoelectric conversion unit has at least one p-i-n structure including a p-type semiconductor layer, an intrinsic semiconductor layer, and an n-type semiconductor layer.

10. The thin film solar cell of claim 9, wherein the intrinsic semiconductor layer of the photoelectric conversion unit contains germanium (Ge).

11. The thin film solar cell of claim 9, wherein the intrinsic semiconductor layer of the photoelectric conversion unit contains at least one of amorphous silicon and microcrystalline silicon.

12. The thin film solar cell of claim 1, wherein a portion of the second front electrode layer that covers the hole contacts the substrate.

13. The thin film solar cell of claim 1, wherein the pin hole has at least one of a circular shape, an oval shape, a lattice shape, a polygon shapes, and an irregular shape.

14. The thin film solar cell of claim 1, wherein the substrate is formed of a transparent non-conductive material.
